(19) United States
(12) Patent Application Publication
(10) Pub. No.: US 2026/0025114 A1
(43) Pub. Date: Jan. 22, 2026

(54) AMPLIFIER EQUALIZER AND BIAS OFFSET CORRECTION

(71) Applicant: MACOM Technology Solutions Holdings, Inc., Lowell, MA (US)

(72) Inventors: Ariel L. Vera Villarroel, Lake Oswego, OR (US); Abdelrahman H. Ahmed, Portland, OR (US)

(21) Appl. No.: 18/778,490

(22) Filed: Jul. 19, 2024

(51) Int. Cl. H03F 3/45

(52) U.S. Cl. CPC H03F 3/45224; H03F 2200/375

(57) ABSTRACT

Amplifiers incorporating equalizer and bias offset correction circuits are described. An example amplifier circuit with equalizer and bias offset correction includes an amplifier with an input, an equalizer circuit coupled to the input of the amplifier, and a bias offset correction circuit coupled to the input of the amplifier. The bias offset correction circuit is configured to adjust a bias potential at the input of the amplifier. In one example, the amplifier is a differential amplifier with differential inputs, the equalizer circuit is coupled to the differential inputs of the amplifier and is configured to adjustably modify a gain of the amplifier over frequency, and the bias offset correction circuit is coupled to the differential inputs of the amplifier and is configured to compensate for modifications to bias potentials at the differential inputs of the amplifier due to operation of the equalizer circuit.

### BACKGROUND

A range of different amplifiers are known and relied upon for data communications. Differential amplifiers, as an example, are commonly used for high-speed data communications. Differential amplifiers are designed to amplify the difference between two input signals and to reject noise or interference that is present on both (i.e., common to) the input signals. Differential amplifiers are often used as the first amplifier stage in operational amplifiers, and multiple stages of differential amplifiers can be cascaded depending on design needs and the amplification application.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

An example amplifier circuit with equalizer and bias offset correction includes an amplifier having an input, an equalizer circuit coupled to the input of the amplifier, and a bias offset correction circuit coupled to the input of the amplifier. The bias offset correction circuit is configured to adjust a bias potential at the input of the amplifier. The equalizer circuit is configured to adjustably modify a gain of the amplifier over frequency. The bias offset correction circuit is configured to adjust the bias potential at the input of the amplifier with closed loop control.

In one example, the amplifier is a differential amplifier with differential inputs, the equalizer circuit is coupled to the differential inputs of the amplifier and is configured to adjustably modify a gain of the amplifier over frequency, and the bias offset correction circuit is coupled to the differential inputs of the amplifier and is configured to compensate for modifications to bias potentials at the differential inputs of the amplifier due to operation of the equalizer circuit.

The equalizer circuit can include a cross-coupled pair of transistors, a capacitor coupled between terminals of the cross-coupled pair of transistors, and a programmable current source and current mirror coupled to the cross-coupled pair of transistors. The cross-coupled pair of transistors can be coupled to the input of the amplifier to modify a gain of the amplifier over frequency. The bias and offset correction circuit can include a variable current source having an output coupled to the input of the amplifier, and a differential amplifier coupled between the input of the amplifier and a control input of the variable current source. The differential amplifier can be a fully differential operational amplifier in one example.

Another amplifier circuit includes an amplifier having an input, an equalizer circuit coupled to the input of the amplifier, and a bias offset correction circuit coupled to the input of the amplifier between the equalizer circuit and the input of the amplifier. The equalizer circuit is configured to adjustably modify a gain of the amplifier over frequency. The bias offset correction circuit is configured to adjust a bias potential at the input of the amplifier with closed loop control.

An example equalizer and bias offset correction circuit includes an equalizer circuit configured to be coupled to an input of an amplifier, and a bias offset correction circuit configured to be coupled to the input of the amplifier. The bias offset correction circuit is configured to adjust a bias potential at the input of the amplifier due to operation of the equalizer circuit. In one aspect, the equalizer circuit is configured to adjustably modify a gain of the amplifier over frequency and imparts a modification to the bias potential at the input of the amplifier according to the equalization adjustment, and the bias offset correction circuit compensates for the modification to the bias potential.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an example amplifier circuit with an equalization, biasing, and offset correction circuit according to various examples described herein.

FIG. 2 illustrates an example amplifier with an equalization, biasing, and offset correction circuit according to various examples described herein.

FIG. 3 illustrates an example amplifier with an equalization, biasing, and offset correction circuit according to various examples described herein.

### DETAILED DESCRIPTION

Receivers, transmitters, and transceivers for emerging data communication applications rely upon amplifier circuits to transfer data signals at higher speeds. The amplifier circuits are often designed for broadband operation and minimal power consumption as much as possible. Newer amplifier circuits are being designed to be adaptive to the communications channel or path over which data is being communicated, which can be helpful to achieve the data rates specified by newer communications standards. The adaptation in amplifiers can be implemented in a number of different ways, such as with programable gain variation across the frequency response, which is commonly referred to as equalization.

Differential amplifiers are commonly used for high-speed data communications. Multiple stages of differential amplifiers can be cascaded or connected in series depending on the design needs of a given amplifier application. It can be important to tailor and optimize the operating criteria and performance of each amplifier stage in a multi-stage amplifier. Often, the quiescent operating point of a given amplifier stage will not match or align with the preceding or following stage in a multi-stage amplifier, and intervening or intermediary circuits are needed for bias shifting and other purposes.

Amplifiers incorporating equalizer and bias offset correction circuits are described herein. An example amplifier circuit with equalizer and bias offset correction includes an amplifier with an input, an equalizer circuit coupled to the input of the amplifier, and a bias offset correction circuit coupled to the input of the amplifier. The bias offset correction circuit is configured to adjust a bias potential at the input of the amplifier. In one example, the amplifier is a differential amplifier with differential inputs, the equalizer circuit is coupled to the differential inputs of the amplifier and is configured to adjustably modify a gain of the amplifier over frequency, and the bias offset correction circuit is coupled to the differential inputs of the amplifier and is configured to compensate for modifications to bias potentials at the differential inputs of the amplifier due to operation of the equalizer circuit.

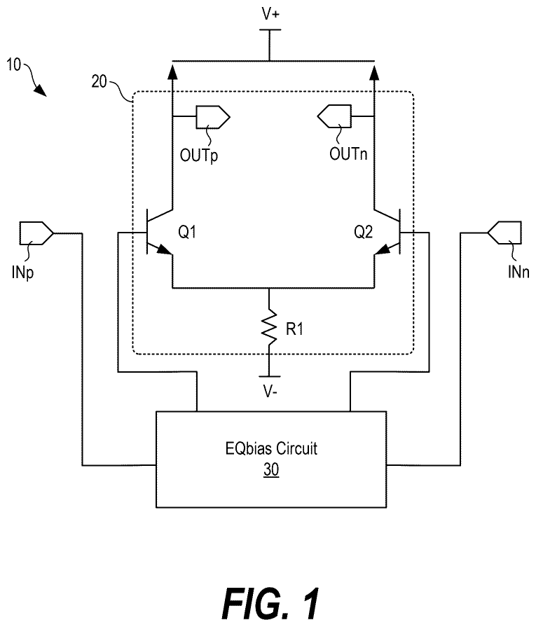

FIG. 1 illustrates an example amplifier circuit 10 according to various examples described herein. The amplifier circuit 10 can be embodied in various ways, such as using discrete components, as an integrated circuit device formed on a substrate, or as a combination of discrete components and integrated devices. The amplifier circuit 10 is provided as a representative example of an amplifier stage with an equalization, biasing, and offset correction circuit. The amplifier circuit 10 is not exhaustively illustrated in FIG. 1, and the amplifier circuit 10 can include additional components that are not shown.

The amplifier circuit 10 includes an amplifier or amplifier stage 20 (also “amplifier 20”) and an equalization, biasing, and offset correction circuit 30 (also “EQbias circuit 30”) among possibly other components. The amplifier 20 can be used as an amplifier stage for radio frequency (RF) communications, for wired communications, for optical communications, or for other purposes, without limitation. The amplifier 20 can also be an amplifier stage in a multi-stage amplifier. The EQbias circuit 30 is coupled inline with the inputs to the amplifier 20. The amplifier 20 is a differential amplifier with differential inputs in the example shown in FIG. 1. However, other types and configurations of amplifiers and amplifier circuits can also incorporate the equalization, biasing, and offset correction concepts described herein.

The amplifier 20 includes transistors Q1 and Q2 and resistor R1. The transistors Q1 and Q2 are embodied as bipolar junction transistors as depicted in FIG. 1. However, the transistors Q1 and Q2 can be embodied as field effect transistors (FETs), and the concepts described herein are not limited to use with amplifiers or transistors of any particular type or technology. The collector of the transistor Q1 is coupled to an upper rail voltage or potential V+, and an output OUTp (e.g., positive or non-inverting output) of the amplifier 20 can be taken from the collector of the transistor Q1. The base of the transistor Q1 operates as an input INp (e.g., positive or non-inverting input) of the amplifier 20. The emitter of the transistor Q1 is coupled to the emitter of the transistor Q2 and to one end of the resistor R1. The other end of the resistor R1 is coupled to the lower rail voltage or potential V−, which can be ground potential in some cases.

The collector of the transistor Q2 is coupled to V+, and an output OUTn (e.g., negative or inverting output) of the amplifier 20 can be taken from the collector of the transistor Q2. The base of the transistor Q2 operates as another input INn (e.g., negative or inverting input) of the amplifier 20. The emitter of the transistor Q2 is coupled to the emitter of the transistor Q1 and to the one end of the resistor R1. The other end of the resistor R1 is coupled to the lower rail voltage or potential V−. The use of a single biasing resistor R1 rather than a current source for biasing the transistors Q1 and Q2 offers a low power solution but results in reduced common-mode rejection for the amplifier 20. In other examples, the amplifier 20 can include a current source or current mirror in place of R1 for biasing the transistors Q1 and Q2, as would be understood in the field, and other variations of the amplifier 20 are within the scope of the embodiments.

The amplifier circuit 10 is not exhaustively illustrated in FIG. 1, and the amplifier circuit 10 can include additional components that are not shown. For example, one or more resistors or other circuit components can be coupled between the transistor Q1 and an upper rail voltage V+, between the transistor Q2 and an upper rail voltage V+, between the emitters of the transistors Q1 and Q2 and the lower rail voltage V−, and at other locations. Coupling, blocking, and other capacitors can also be relied upon as would be understood in the field. In some cases, the resistor R1 can be replaced by a current source, and other circuit variations are within the scope of the embodiments.

The upper rail voltage V+ can be any suitable voltage, and the lower rail voltage V− can be any suitable voltage or potential (e.g., including ground potential in some cases) that is less than the upper rail voltage V+. The voltages V+ and V− can be selected, respectively, based on the target biasing voltage or voltage range for the amplifier circuit 10. The difference in potential between the voltages V+ and V− can be any suitable potential difference based on the target biasing voltage or voltage range for the amplifier circuit 10.

The amplifier 20 can be an amplifier stage among several stages in a multi-stage amplifier. The EQbias circuit 30 is coupled inline with the INp and INn inputs to the amplifier 20 as shown in FIG. 1. The EQbias circuit 30 includes a number of circuit blocks for different purposes, including an equalizer circuit and a bias offset correction circuit, as described in further detail below. The equalizer circuit in the EQbias circuit 30 is configured to adjustably modify a gain of the amplifier 20 over frequency, such as over the operating band of frequencies for the amplifier 20 or at least portion of the operating bandwidth for the amplifier 20. Thus, the amplifier circuit 10 can provide adaptive or adaptable gain based on the EQbias circuit 30. The EQbias circuit 30 can also implement programable gain variation across the operating band of the amplifier 20 as described below.

In some operating modes, the equalizer circuit in the EQbias circuit 30 can alter or modify the bias potentials (e.g., DC bias potentials) of the input signals provided to the INp and INn inputs. More particularly, the equalizer circuit in the EQbias circuit 30 can alter or modify the bias potentials of the input signals between the INp and INn inputs and the base terminal inputs of the transistors Q1 and Q2. The modification of the bias potentials at the base terminal inputs of the transistors Q1 and Q2 can result in a range of issues, such as the transistors Q1 and Q2 of the amplifier 20 cutting or pinching off, excessive current flow through the transistors Q1 and Q2, saturation of the transistors Q1 and Q2, distortion, and other issues. Thus, although the equalizer circuit provides adjustable modification of the gain of the amplifier 20 over frequency, it can also cause undesirable biasing problems for the amplifier 20.

The bias offset correction circuit in the EQbias circuit 30 is configured to compensate for modifications to bias potentials that may be caused by the equalizer circuit. The bias offset correction circuit is configured to adjust the bias potentials at the base terminal inputs of the transistors Q1 and Q2 with closed loop control. These and other aspects of the EQbias circuit 30 are described below.

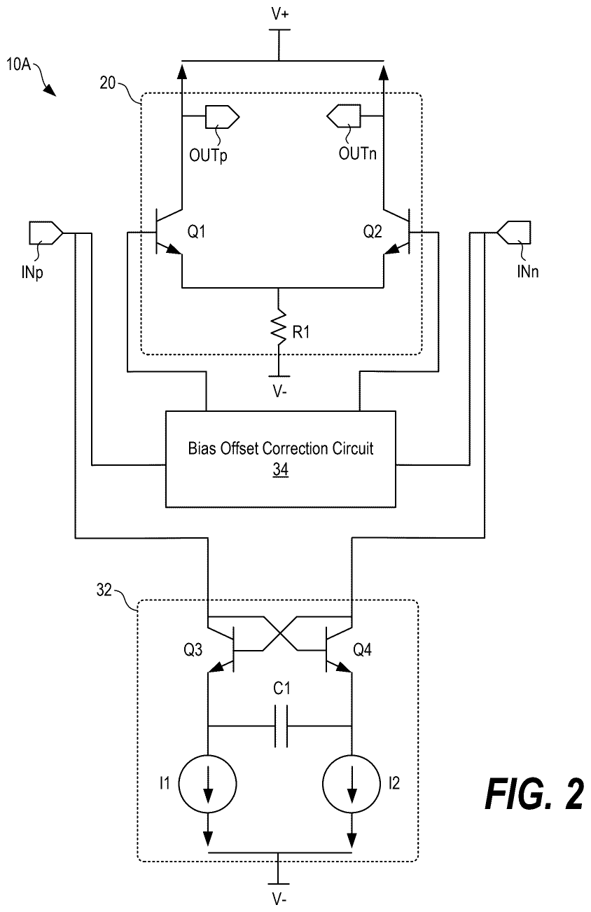

FIG. 2 illustrates an example amplifier 10A according to various examples described herein. The amplifier circuit 10A can be embodied in various ways, such as using discrete components, as an integrated circuit device formed on a substrate, or as a combination of discrete components and integrated devices. The amplifier circuit 10A is provided as a representative example of an amplifier stage with an equalization, biasing, and offset correction circuit. The amplifier circuit 10A is not exhaustively illustrated in FIG. 2, and the amplifier circuit 10A can include additional components that are not shown.

The amplifier circuit 10A includes the amplifier 20, which is similar to that shown in FIG. 1 and described above, an equalizer circuit 32, and a bias offset correction circuit 34. The equalizer circuit 32 includes a cross-coupled pair of transistors Q3 and Q4, a capacitor C1, and current sources I1 and I2. The base terminal of the transistor Q3 is coupled to the collector of the transistor Q4, and the base terminal of the transistor Q4 is coupled to the collector of the transistor Q3. The capacitor C1 is coupled between the emitters of the transistors Q3 and Q4. The collectors of the transistors Q3 and Q4 are also coupled to the INp and INn inputs of the amplifier circuit 10A. The current source I1 is coupled between the emitter of the Q3 and the lower rail voltage or potential V−. The current source I2 is coupled between the emitter of the Q4 and the lower rail voltage or potential V−.

The current sources I1 and I2 are representative, and each can be implemented as any suitable type of current source or related biasing circuitry for the transistors Q3 and Q4. Examples of the current sources I1 and I2 include transistor-based current mirrors, current regulators, resistors, and combinations thereof, but the current sources I1 and I2 are not limited to any particular type of implementation. The current sources I1 and I2 can also be implemented or embodied as variable current sources, and an example implementation using a variable current source is described below.

The equalizer circuit 32 provides a type of impedance transformation and, when coupled across the INp and INn inputs of the amplifier circuit 10A as shown in FIG. 2, is configured to adjustably modify a gain of the amplifier 20 over frequency. For example, the current of the current source I1 can be varied or altered, the current of the current source I2 can be varied or altered, or the currents of both the current source I1 and I2 can be varied. The adjustment of the current sources I1 and I2 results in a corresponding variation in the currents through the transistors Q3 and Q4. This leads to a change in the transformed impedance of the equalizer circuit 32 and modification of a gain of the amplifier 20 over frequency, such as a gain alteration over certain frequency ranges for the amplifier 20.

The adjustment of the currents through the transistors Q3 and Q4 in the equalizer circuit 32 can also result in a modification of the bias potentials (e.g., DC bias potentials) at the INp and INn inputs. Further, adjustment of the currents through the transistors Q3 and Q4 can modify the bias potentials of the input signals at the base terminal inputs of the transistors Q1 and Q2. Thus, operation of the equalizer circuit 32 imparts a modification to the bias potentials at the base terminal inputs of the transistors Q1 and Q2 during equalization adjustment. In some cases, the modification of the bias potentials can result in the transistors Q1 and Q2 of the amplifier 20 cutting or pinching off, excessive current flow through the transistors Q1 and Q2, saturation of the transistors Q1 and Q2, distortion, and other issues.

The bias offset correction circuit 34 is configured to compensate for modifications to bias potentials that may be caused by the equalizer circuit 32 over time. The bias offset correction circuit 34 is coupled between the INp and INn inputs of the amplifier circuit 10A and the base terminal inputs of the transistors Q1 and Q2. The bias offset correction circuit 34 is able to adjust the bias potentials at the base terminal inputs of the transistors Q1 and Q2, by charge sourcing or sinking, with closed loop control.

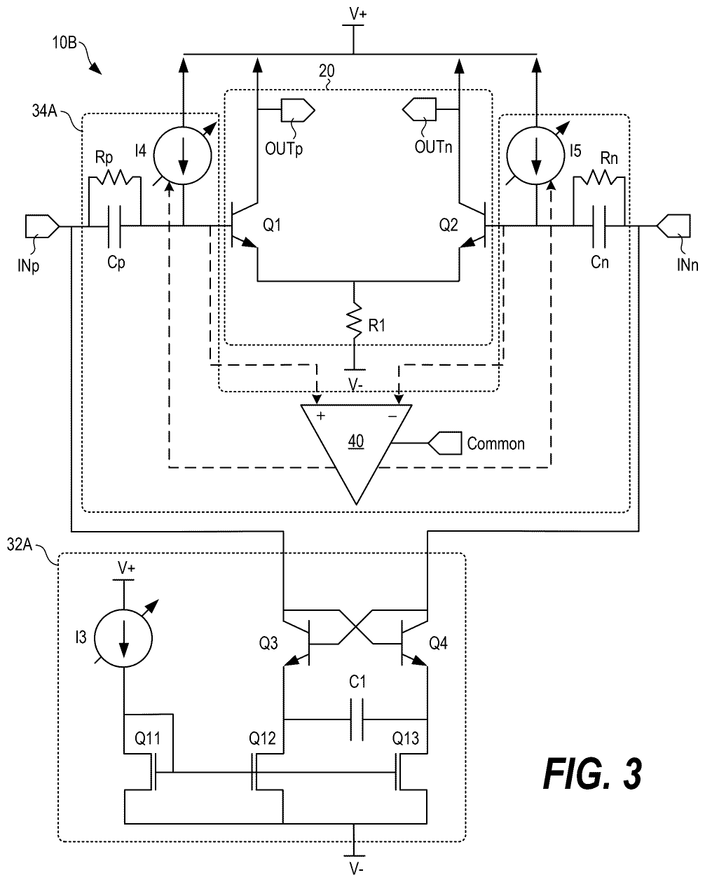

FIG. 3 illustrates an example amplifier circuit 10B according to various examples described herein. The amplifier circuit 10B can be embodied in various ways, such as using discrete components, as an integrated circuit device formed on a substrate, or as a combination of discrete components and integrated devices. The amplifier circuit 10B is provided as a representative example of an amplifier stage with an equalization, biasing, and offset correction circuit. The amplifier circuit 10B is not exhaustively illustrated in FIG. 3, and the amplifier circuit 10B can include additional components that are not shown.

The amplifier circuit 10B includes the amplifier 20, which is similar to that shown in FIG. 1 and described above, an equalizer circuit 32A, and a bias offset correction circuit 34A. The equalizer circuit 32A includes a cross-coupled pair of transistors Q3 and Q4, a capacitor C1, a variable current source I3, and a current mirror of transistors Q11, Q12, and Q13. The base terminal of the transistor Q3 is coupled to the collector of the transistor Q4, and the base terminal of the transistor Q4 is coupled to the collector of the transistor Q3. The capacitor C1 is coupled between the emitters of the transistors Q3 and Q4. The collectors of the transistors Q3 and Q4 are also coupled to the INp and INn inputs of the amplifier circuit 10A.

The variable current source I3 is representative and can be implemented as a type of current source or related biasing circuit with a variable and selectable or programmable current output. Examples of the variable current source I3 include transistor-based current mirrors and current regulators, including circuits that will generate a variable current output based on an applied bias voltage, rail voltage, temperature variation, or other control factor or combinations thereof. The variable current source I3 is not limited to any particular type of implementation. The output current from the variable current source I3 can be programmable, or programmatically selected, by a digital or analog control signal from a control circuit (not shown), for example.

In the current mirror of transistors Q11, Q12, and Q13, the transistors Q12 and Q13 are electrically coupled and configured to mirror the current flowing through the transistor Q11. The current flowing through the transistor Q11 is set by the output current from the variable current source I3, which can be varied or altered based on a control signal, for example, or other control scheme. The transistors Q12 and Q13 mirror or track the current through the transistor Q11, as it varies based on the output current from the variable current source I3, based on the arrangement of the transistors Q11, Q12, and Q13 as a current mirror.

The equalizer circuit 32A provides a type of impedance transformation and, when coupled across the INp and INn inputs of the amplifier circuit 10B as shown in FIG. 3, is configured to adjustably modify a gain of the amplifier 20 over frequency. For example, the current of the current source I3 can be varied or altered based on a control signal, for example, or other control scheme. The current from the current source I3 is input through the transistor Q11. The transistors Q12 and Q13 track or mirror the current through the transistor Q11, as it varies based on the output current from the variable current source I3. In turn, the currents through the transistors Q12 and Q13 set the currents through the transistors Q3 and Q4, respectively.

Changes to the currents through the transistors Q3 and Q4 leads to a change in the transformed impedance of the equalizer circuit 32A and modification of a gain of the amplifier 20 over frequency, such as a gain alteration over certain frequency ranges for the amplifier 20. Thus, the gain of the amplifier 20 can be programmable or programmatically selected by a digital or analog control signal from a control circuit (not shown) provided to the variable current source I3, for example.

The adjustment of the currents through the transistors Q3 and Q4 in the equalizer circuit 32A can also result in a modification of the bias potentials (e.g., DC bias potentials) at the INp and INn inputs. The bias offset correction circuit 34A is configured to compensate for modifications to bias potentials that may be caused by the equalizer circuit 32A. The bias offset correction circuit 34A is coupled between the INp and INn inputs of the amplifier circuit 10B and the base terminal inputs of the transistors Q1 and Q2. The bias offset correction circuit 34A is able to adjust the bias potentials at the base terminal inputs of the transistors Q1 and Q2, by charge sourcing with closed loop control.

The bias offset correction circuit 34A includes a first isolation impedance at the INp input, a second isolation impedance at the INn input, a first variable current source I4, a second variable current source I5, and a differential operational amplifier 40 (also “differential amplifier 40”), among possibly other components. The first isolation impedance includes the resistor Rp and the capacitor Cp, which are coupled in parallel. The parallel combination of Rp and Cp is coupled between the INp input and the base terminal of the transistor Q1. The second isolation impedance includes the resistor Rn and the capacitor Cn, which are also coupled in parallel. The parallel combination of Rn and Cn is coupled between the INn input and the base terminal of the transistor Q2. The first and second isolation impedances are described in further detail below.

The variable current source I4 is coupled between the upper rail voltage or potential V+ and the base terminal of the transistor Q1. The variable current source I5 is coupled between the upper rail voltage or potential V+ and the base terminal of the transistor Q2. The output current of the variable current source I4 is directed or controlled by a first control signal (e.g., at a non-inverting output) provided by the differential amplifier 40, and the output current of the variable current source I5 is directed or controlled by a second control signal (e.g., at an inverting output) provided by the differential amplifier 40.

The variable current sources I4 and I5 are representative and can be implemented as a type of current source or related biasing circuit with a variable current output. Examples of the variable current sources I4 and I5 include transistor-based current mirrors and current regulators, including circuits that will generate a variable current output based on an applied bias voltage or other control signal. The variable current sources I4 and I5 are not limited to any particular type of implementation.

In the example depicted in FIG. 3, it is expected that the target bias voltage at the base terminals of Q1 and Q2 will be above the input common-mode voltage under all operating conditions and process, voltage, and temperature variations. Thus, the variable current sources I4 and I5 are arranged to source or inject charge to the nodes between base terminals of Q1 and Q2 and resistors Rp and Rn, respectively. In other circuit configurations, however, the variable current sources I4 and I5 can be arranged to sink charge from the nodes between base terminals of Q1 and Q2 and resistors Rp and Rn based on control signals provided by the differential amplifier 40.

The differential amplifier 40 can be embodied as a fully differential operational amplifier in one example. The differential amplifier 40 includes differential (i.e., dual) inputs and differential outputs in the example shown in FIG. 3. The inputs to the differential amplifier 40 include, at the non-inverting input, a first input potential coupled from the base terminal of the transistor Q1 and, at the inverting input, a second input potential coupled from the base terminal of the transistor Q2. The inputs to the differential amplifier 40 can be switched between the base terminals of the transistors Q1 and Q2, however. In any case, the differential amplifier 40 in the bias offset correction circuit 34A is configured to compare the voltages or potentials among or between the base terminals of the transistors Q1 and Q2.

The output of the differential amplifier 40 is a differential signal provided across differential outputs of the differential amplifier 40. The outputs from the differential amplifier 40 include, at a non-inverting output, a first control signal provided to the variable current source I4 and, at an inverting output, a second control signal provided to the variable current source I5. In differential operation, the differential amplifier 40 is configured to direct the first and second control signals to reduce any difference in the bias voltages between the base terminals of the transistors Q1 and Q2, based on the potentials coupled from the base terminals of the transistors Q1 and Q2. Moreover, while the relative difference between the bias voltages is reduced, the absolute or common-mode bias voltage is set to be equal to the reference voltage “Common” as shown in FIG. 3. The differential amplifier 40 thus controls the output currents provided by both the variable current sources I4 and I5 based on the voltages or potentials at the base terminals of the transistors Q1 and Q2. The variable current sources I4 and I5 can be directed, at least in part, based on a difference in the voltages or potentials at the base terminals of the transistors Q1 and Q2.

An increase in the current generated by the current source I4 will, in turn, increase the bias voltage at the base of the transistor Q1. Similarly, an increase in the current generated by the current source I5 will, in turn, increase the bias voltage at the base of the transistor Q2. Thus, the bias offset correction circuit 34A is configured to and capable of generating a bias offset (e.g., a DC bias increase) at the base terminals of the transistors Q1 and Q2. The bias offset generated by the bias offset correction circuit 34A can compensate for a modification of the bias potentials (e.g., DC bias potentials) at the INp and INn inputs that may be attributable to or caused by the equalizer circuit 32A, as described herein.

The common-mode output voltage among the differential outputs of the differential amplifier 40 can also be controlled independently. In the example shown in FIG. 3, the common-mode output voltage on the differential outputs of the differential operational amplifier 40 is controlled by a common-mode reference input signal “Common,” as shown in FIG. 3. A controller (not shown) can set the voltage or potential of the common-mode reference input signal for the differential operational amplifier 40. The common-mode reference input signal can be developed by an output of a digital-to-analog converter (DAC), for example, based on a digital input signal to the DAC provided from a controller, as one example.

The first isolation impedance of the resistor Rp and the capacitor Cp serves to separate the potential at the INp input and the base terminal of the transistor Q1, so that the variable current source I4 can provide bias offset control. Similarly, the second isolation impedance of the resistor Rn and the capacitor Cn serves to separate the potential at the INn input and the base terminal of the transistor Q2, so that the variable current source I5 can provide bias offset control. At high frequencies, the resistors Rp and Rn and the input impedances of the transistors Q1 and Q2 can limit the frequency response of the amplifier circuit 10B, particularly compared to the case without the resistors Rp and Rn. The capacitors Cp and Cn are added in parallel with the resistors Rp and Rn, to improve the frequency response of the amplifier circuit 10B. The resistances and capacitances of the resistors Rp and Rn and capacitors Cp and Cn can be selected based on design needs and the desired frequency response of the amplifier circuit 10B.

The transistors described herein, including the transistors Q1, Q2, Q3, and Q4, can be implemented as a range of different types of transistors formed in a range of different semiconductor materials. The transistors can be formed as bipolar junction transistors or FETs, although the concepts can be applied to other types of transistors. Among other types of FET transistors, the transistors described herein can be formed as high-electron mobility transistors (HEMTs), pseudomorphic high-electron mobility transistors (pHEMTs), metamorphic high-electron mobility transistors (mHEMTs), and other types of transistors. The FETs can include metal oxide or insulator semiconductor (MOSFET or MISFET) transistors and metal-semiconductor field-effect transistor (MESFETs). The transistors can include one or more field plates, such as source-connected field plates, gate-connected field plates, or both source-connected and gate-connected field plates. The transistors can be implemented in gallium arsenide (GaAs), gallium nitride (GaN), GaN materials, and other semiconductor materials on or over a range of different substrates. As non-limiting examples, the transistors can be structured as enhancement or depletion mode FET transistors, such as a depletion mode GaAs pHEMT transistors, as GaN HEMT transistors, as GaN materials HEMT transistors, or as related power transistors.

The transistors and other active devices described herein can be formed using group III-V semiconductor materials and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)-, gallium (Ga)-, indium (In)-, and alloys (AlGaIn)-based Nitrides), GaAs, InP, InGaP, AlGaAs, etc. devices. However, the concepts may be applied to transistors and other active devices formed from other semiconductor materials.

The concepts described herein can be embodied by GaN-on-Si transistors and devices, GaN-on-SiC transistors and devices, as well as other types of semiconductor materials. As used herein, the phrase “gallium nitride material(s)” or “GaN material(s)” refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}, aluminum indium gallium arsenide phosphide nitride (AlₓIn_{y}Ga_{(1-x-y)}AsₐP_{b}N_{(1-a-b)}), among others. Typically, when present, arsenic and/or phosphorous are at low concentrations (e.g., less than 5 weight percent). The gallium nitride materials can be n-type doped, p-type doped, or unintentionally doped (UID).

In embodiments with high concentrations of gallium, gallium nitride material has a high concentration of gallium and includes little or no aluminum or indium. In high gallium concentration embodiments, the sum of (x+y) may be less than 0.4 in some cases, less than 0.2 in some cases, less than 0.1 in some cases, or even less in other cases. The term “gallium nitride” or “GaN” refers directly to gallium nitride, exclusive of its alloys (i.e., x=y=a=b=0). The GaN can be n-type doped, p-type doped, or unintentionally doped (UID).

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially available semiconductor processing tools available at the time, the terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

1. An amplifier circuit with equalizer and bias offset correction comprising:
an amplifier comprising an input;
an equalizer circuit coupled to the input of the amplifier; and
a bias offset correction circuit coupled to the input of the amplifier, the bias offset correction circuit being configured to adjust a bias potential at the input of the amplifier.

2. The amplifier circuit according to claim 1, wherein the equalizer circuit is configured to adjustably modify a gain of the amplifier over frequency.

3. The amplifier circuit according to claim 1, wherein the bias offset correction circuit is configured to adjust the bias potential at the input of the amplifier with closed loop control.

4. The amplifier circuit according to claim 1, wherein:
the equalizer circuit is configured to adjustably modify a gain of the amplifier over frequency;
the equalizer circuit imparts a modification to the bias potential at the input of the amplifier during equalization adjustment; and
the bias offset correction circuit compensates for the modification to the bias potential.

5. The amplifier circuit according to claim 1, wherein the equalizer circuit comprises:
a cross-coupled pair of transistors;
a capacitor coupled between terminals of the cross-coupled pair of transistors; and
a programmable current source and current mirror coupled to the cross-coupled pair of transistors.

6. The amplifier circuit according to claim 5, wherein the cross-coupled pair of transistors is coupled to the input of the amplifier to modify a gain of the amplifier over frequency.

7. The amplifier circuit according to claim 1, wherein the bias and offset correction circuit comprises:
a variable current source having an output coupled to the input of the amplifier; and
a differential amplifier coupled between the input of the amplifier and a control input of the variable current source.

8. The amplifier circuit according to claim 1, further comprising isolation impedances coupled between the equalizer circuit and the bias offset correction circuit.

9. The amplifier circuit according to claim 1, wherein:
the amplifier comprises a differential amplifier with differential inputs;
the equalizer circuit is coupled to the differential inputs of the amplifier and is configured to adjustably modify a gain of the amplifier over frequency; and
the bias offset correction circuit is coupled to the differential inputs of the amplifier and is configured to compensate for modifications to bias potentials at the differential inputs of the amplifier due to operation of the equalizer circuit.

10. An amplifier circuit, comprising:
an amplifier comprising an input;
an equalizer circuit coupled to the input of the amplifier; and
a bias offset correction circuit coupled to the input of the amplifier between the equalizer circuit and the input of the amplifier.

11. The amplifier circuit according to claim 10, wherein the equalizer circuit is configured to adjustably modify a gain of the amplifier over frequency.

12. The amplifier circuit according to claim 10, wherein the bias offset correction circuit is configured to adjust a bias potential at the input of the amplifier with closed loop control.

13. The amplifier circuit according to claim 10, wherein:
the equalizer circuit imparts a modification to a bias potential at the input of the amplifier during equalization adjustment; and
the bias offset correction circuit compensates for the modification to the bias potential.

14. The amplifier circuit according to claim 10, wherein the equalizer circuit comprises:
a cross-coupled pair of transistors;
a capacitor coupled between terminals of the cross-coupled pair of transistors; and
a programmable current source and current mirror coupled to the cross-coupled pair of transistors.

15. The amplifier circuit according to claim 14, wherein the cross-coupled pair of transistors is coupled to the input of the amplifier to modify a gain of the amplifier over frequency.

16. The amplifier circuit according to claim 10, wherein the bias and offset correction circuit comprises:
a variable current source having an output coupled to the input of the amplifier; and
a differential amplifier coupled between the input of the amplifier and a control input of the variable current source.

17. The amplifier circuit according to claim 10, wherein:
the amplifier comprises a differential amplifier with differential inputs;
the equalizer circuit is coupled to the differential inputs of the amplifier and is configured to adjustably modify a gain of the amplifier over frequency; and
the bias offset correction circuit is coupled to the differential inputs of the amplifier and is configured to compensate for modifications to bias potentials at the differential inputs of the amplifier due to operation of the equalizer circuit.

18. An equalizer and bias offset correction circuit, comprising:
an equalizer circuit configured to be coupled to an input of an amplifier; and
a bias offset correction circuit configured to be coupled to the input of the amplifier, the bias offset correction circuit being configured to adjust a bias potential at the input of the amplifier due to operation of the equalizer circuit.

19. The equalizer and bias offset correction circuit according to claim 18, wherein:
the equalizer circuit is configured to adjustably modify a gain of the amplifier over frequency and imparts a modification to the bias potential at the input of the amplifier during equalization adjustment; and
the bias offset correction circuit compensates for the modification to the bias potential.

20. The equalizer and bias offset correction circuit according to claim 18, wherein:
the equalizer circuit is configured to be coupled to differential inputs of the amplifier and adjustably modify a gain of the amplifier over frequency; and
the bias offset correction circuit is configured to be coupled to the differential inputs of the amplifier and to compensate for modifications to bias potentials at the differential inputs of the amplifier due to operation of the equalizer circuit.
